(19) United States
(12) Patent Application Publication
(10) Pub. No.: US 2006/0056233 A1
(43) Pub. Date: Mar. 16, 2006

(54) Using a phase change memory as a replacement for a buffered flash memory

(76) Inventors: Ward D. Parkinson, Boise, ID (US); Manzur Gill, Cupertino, CA (US)

Correspondence Address: TROP PRUNER & HU, PC, 8554 KATY FREEWAY, SUITE 100, HOUSTON, TX, 77024, US

(21) Appl. No.: 10/938,705

(22) Filed: Sep. 10, 2004

(51) Int. Cl. G11C 11/00; G11C 5/06

(52) U.S. Cl. 365/163; 365/63

(57) ABSTRACT

A phase change memory may be utilized to replace NAND flash memory in combination with a buffer such as a static random access memory and/or a dynamic random access memory. Because the phase change memory may have sufficiently low cost, it may replace low cost NAND flash and because the phase change memory has sufficiently high performance, it can also replace the dynamic random access or static random access buffer memory sometimes packaged with the NAND flash memory. Thus, a relatively low cost, high performance solution is achieved in a relatively small package size in some embodiments.

### BACKGROUND

This invention relates generally to processor-based systems.

Processor-based systems may include any device with a specialized or general purpose processor. Examples of such systems include personal computers, laptop computers, personal digital assistants, cell phones, cameras, web tablets, electronic games, and media devices, such as digital versatile disk players, to mention a few examples.

Conventionally, such devices use either semiconductor memory, hard disk drives, or some combination of the two as storage. One common semiconductor memory is a NAND flash device. Compared to other flash devices, it may have acceptable performance in some cases at lower costs. To improve its performance, the NAND flash may be coupled to a buffer. For example, a stack of a NAND flash device and a buffer, such as a dynamic random access memory or a static random access memory, may be sold as a packaged unit.

One problem with buffered NAND flash memory solutions for processor-based systems is that such a stack may have a larger size and space requirement than may be desirable in some applications. Another problem is that flash memories are block erased which tends to make them slow in some applications.

Thus, there is a need for improved processor-based systems.

### BRIEF DESCRIPTION OF THE DRAWINGS

FIG. 1 is a schematic depiction of a portion of an array in one embodiment of the present invention;

FIG. 2 is a schematic and cross-sectional view of a cell in accordance with one embodiment of the present invention;

FIG. 3 is a perspective view of a memory stack in accordance with one embodiment of the present invention; and

FIG. 4 is a system depiction of one embodiment of the present invention.

### DETAILED DESCRIPTION

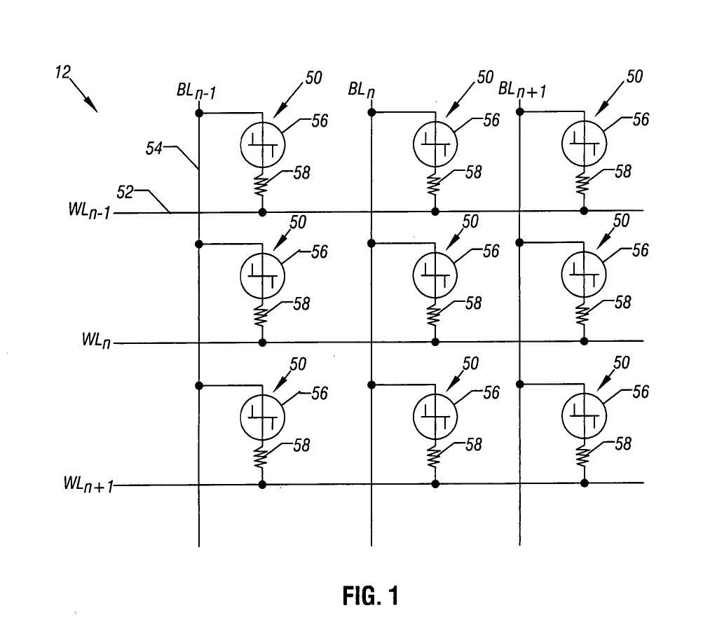

Referring to FIG. 1, a non-volatile memory may include a variable resistance memory array 12. The memory, in one embodiment, may be a phase change memory. The variable resistance memory array 12 may include a plurality of cells 50 arranged in rows and columns. The cells 50 may include a phase change memory element 56 and a selection device 58 in one embodiment. In one embodiment, a cell 50 may be associated with a word line 52, addressable by a word line decoder and a bit line or column line 54, addressable by a bit line decoder.

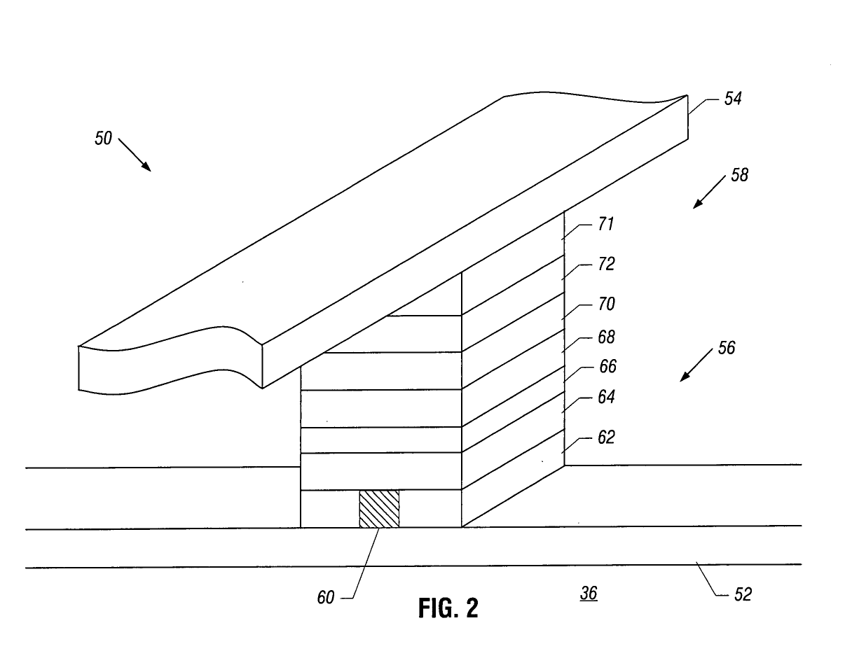

Referring to FIG. 2, a cell 50 in the array 12 may be formed over a substrate 36. The substrate 36, in one embodiment, may include the conductive word line 52 coupled to a selection device 58. The selection device 58, in one embodiment, may be formed in the substrate 36 and may, for example, be a diode, transistor, or a non-programmable chalcogenide selection device.

The selection device 58 may be formed of a non-programmable chalcogenide material including a top electrode 71, a chalcogenide material 72, and a bottom electrode 70. The selection device 58 may be permanently in the reset state in one embodiment. While an embodiment is illustrated in which the selection device 58 is positioned over the phase change memory element 56, the opposite orientation may be used as well.

Conversely, the phase change memory element 56 may be capable of assuming either a set or reset state, explained in more detail hereinafter. The phase change memory element 56 may include an insulator 62, a phase change memory material 64, a top electrode 66, and a barrier film 68, in one embodiment of the present invention. A lower electrode 60 may be defined within the insulator 62 in one embodiment of the present invention.

In one embodiment, the phase change material 64 may be a phase change material suitable for non-volatile memory data storage. A phase change material may be a material having electrical properties (e.g., resistance) that may be changed through the application of energy such as, for example, heat, light, voltage potential, or electrical current.

Examples of phase change materials may include a chalcogenide material or an ovonic material. An ovonic material may be a material that undergoes electronic or structural changes and acts as a semiconductor once subjected to application of a voltage potential, electrical current, light, heat, etc. A chalcogenide material may be a material that includes at least one element from column VI of the periodic table or may be a material that includes one or more of the chalcogen elements, e.g., any of the elements of tellurium, sulfur, or selenium. Ovonic and chalcogenide materials may be non-volatile memory materials that may be used to store information.

In one embodiment, the memory material 64 may be chalcogenide element composition from the class of tellurium-germanium-antimony (TeₓGe_{y}Sb_{z}) material or a GeSbTe alloy, although the scope of the present invention is not limited to just these materials.

In one embodiment, if the memory material 64 is a non-volatile, phase change material, the memory material may be programmed into one of at least two memory states by applying an electrical signal to the memory material. An electrical signal may alter the phase of the memory material between a substantially crystalline state and a substantially amorphous state, wherein the electrical resistance of the memory material 64 in the substantially amorphous state is greater than the resistance of the memory material in the substantially crystalline state. Accordingly, in this embodiment, the memory material 64 may be adapted to be altered to a particular one of a number of resistance values within a range of resistance values to provide digital or analog storage of information.

Programming of the memory material to alter the state or phase of the material may be accomplished by applying voltage potentials to the lines 52 and 54, thereby generating a voltage potential across the memory material 64. An electrical current may flow through a portion of the memory material 64 in response to the applied voltage potentials, and may result in heating of the memory material 64.

This heating and subsequent cooling may alter the memory state or phase of the memory material 64. Altering the phase or state of the memory material 64 may alter an electrical characteristic of the memory material 64. For example, resistance of the material 64 may be altered by altering the phase of the memory material 64. The memory material 64 may also be referred to as a programmable resistive material or simply a programmable resistance material.

In one embodiment, a voltage potential difference of about 0.5 to 1.5 volts may be applied across a portion of the memory material by applying about 0 volts to a line 52 and about 0.5 to 1.5 volts to an upper line 54. A current flowing through the memory material 64 in response to the applied voltage potentials may result in heating of the memory material. This heating and subsequent cooling may alter the memory state or phase of the material.

In a “reset” state, the memory material may be in an amorphous or semi-amorphous state and in a “set” state, the memory material may be in a crystalline or semi-crystalline state. The resistance of the memory material in the amorphous or semi-amorphous state may be greater than the resistance of the material in the crystalline or semi-crystalline state. The association of reset and set with amorphous and crystalline states, respectively, is a convention. Other conventions may be adopted.

Due to electrical current, the memory material 64 may be heated to a relatively higher temperature to amorphisize memory material and “reset” memory material. Heating the volume or memory material to a relatively lower crystallization temperature may crystallize memory material and “set” memory material. Various resistances of memory material may be achieved to store information by varying the amount of current flow and duration through the volume of memory material, or by tailoring the edge rate of the trailing edge of the programming current or voltage pulse.

The information stored in memory material 64 may be read by measuring the resistance of the memory material. As an example, a read current may be provided to the memory material using opposed lines 54, 52 and a resulting read voltage across the memory material may be compared against a reference voltage using, for example, the sense amplifier 20. The read voltage may be proportional to the resistance exhibited by the memory storage element.

In order to select a cell 50 on column 54 and row 52, the selection device 58 for the selected cell 50 at that location may be operated. The selection device 58 activation allows current to flow through the memory element 56 in one embodiment of the present invention.

In a low voltage or low field regime A, the device 58 is off and may exhibit very high resistance in some embodiments. The off resistance can, for example, range from 100,000 ohms to greater than 10 gigaohms at a bias of half the threshold voltage. The device 58 may remain in its off state until a threshold voltage V_{T} or threshold current I_{T} switches the device 58 to a highly conductive, low resistance on state. The voltage across the device 58 after turn on drops to a slightly lower voltage, called the holding voltage V_{H} and remains very close to the threshold voltage. In one embodiment of the present invention, as an example, the threshold voltage may be on the order of 1.1 volts and the holding voltage may be on the order of 0.9 volts.

After passing through the snapback region, in the on state, the device 58 voltage drop remains close to the holding voltage as the current passing through the device is increased up to a certain, relatively high, current level. Above that current level the device remains on but displays a finite differential resistance with the voltage drop increasing with increasing current. The device 58 may remain on until the current through the device 58 is dropped below a characteristic holding current value that is dependent on the size and the material utilized to form the device 58.

In some embodiments of the present invention, the selection device 58 does not change phase. It remains permanently amorphous and its current-voltage characteristics may remain the same throughout its operating life.

As an example, for a 0.5 micrometer diameter device 58 formed of TeAsGeSSe having respective atomic percents of 16/13/15/1/55, the holding current may be on the order of 0.1 to 100 micro-ohms in one embodiment. Below this holding current, the device 58 turns off and returns to the high resistance regime at low voltage, low field. The threshold current for the device 58 may generally be of the same order as the holding current. The holding current may be altered by changing process variables, such as the top and bottom electrode material and the chalcogenide material. The device 58 may provide high “on current” for a given area of device compared to conventional access devices such as metal oxide semiconductor field effect transistors or bipolar junction transistors.

In some embodiments, the higher current density of the device 58 in the on state allows for higher programming current available to the memory element 56. Where the memory element 56 is a phase change memory, this enables the use of larger programming current phase change memory devices, reducing the need for sub-lithographic feature structures and the commensurate process complexity, cost, process variation, and device parameter variation.

One technique for addressing the array 12 uses a voltage V applied to the selected column and a zero voltage applied to the selected row. For the case where the device 56 is a phase change memory, the voltage V is chosen to be greater than the device 58 maximum threshold voltage plus the memory element 56 reset maximum threshold voltage, but less than two times the device 58 minimum threshold voltage. In other words, the maximum threshold voltage of the device 58 plus the maximum reset threshold voltage of the device 56 may be less than V and V may be less than two times the minimum threshold voltage of the device 58 in some embodiments. All of the unselected rows and columns may be biased at V/2.

With this approach, there is no bias voltage between the unselected rows and unselected columns. This reduces background leakage current.

After biasing the array in this manner, the memory elements 56 may be programmed and read by whatever means is needed for the particular memory technology involved. A memory element 56 that uses a phase change material may be programmed by forcing the current needed for memory element phase change or the memory array can be read by forcing a lower current to determine the device 56 resistance.

For the case of a phase change memory element 56, programming a given selected bit in the array 12 can be as follows. Unselected rows and columns may be biased as described for addressing. Zero volts is applied to the selected row. A current is forced on the selected column with a compliance that is greater than the maximum threshold voltage of the device 58 plus the maximum threshold voltage of the device 56. The current amplitude, duration, and pulse shape may be selected to place the memory element 56 in the desired phase and thus, the desired memory state.

Reading a phase change memory element 56 can be performed as follows. Unselected rows and columns may be biased as described previously. Zero volts is applied to the selected row. A voltage is forced at a value greater than the maximum threshold voltage of the device 58, but less than the minimum threshold voltage of the device 58 plus the minimum threshold voltage of the element 56 on the selected column. The current compliance of this forced voltage is less than the current that could program or disturb the present phase of the memory element 56. If the phase change memory element 56 is set, the access device 58 switches on and presents a low voltage, high current condition to a sense amplifier. If the device 16 is reset, a larger voltage, lower current condition may be presented to the sense amplifier. The sense amplifier can either compare the resulting column voltage to a reference voltage or compare the resulting column current to a reference current.

The above-described reading and programming protocols are merely examples of techniques that may be utilized. Other techniques may be utilized by those skilled in the art.

To avoid disturbing a set bit of memory element 56 that is a phase change memory, the peak current may equal the threshold voltage of the device 58 minus the holding voltage of the device 58 that quantity divided by the total series resistance including the resistance of the device 58, external resistance of device 56, plus the set resistance of device 56. This value may be less than the maximum programming current that will begin to reset a set bit for a short duration pulse.

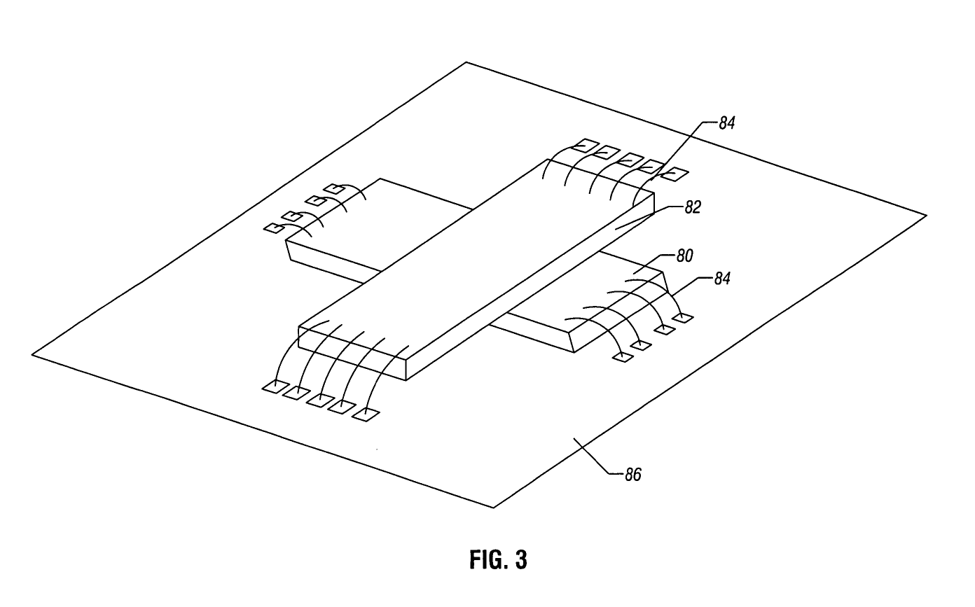

Referring to FIG. 3, in one embodiment of the present invention, a stack of packaged integrated circuit phase change memories may be provided in packages 80, 82 coupled by wires 84 to an appropriate interconnection device, such as a printed circuit board 86. Each packaged integrated circuit phase change memory 80, 82 may have a generally rectangular shape. One or more packaged integrated circuit phase change memories 82 may be stacked on top of the integrated circuit 80. In one embodiment, the stacked integrated circuits 82 may be arranged transversely to the underlying integrated circuit phase change memory 80, as shown in FIG. 3. The circuits 80 and 82 may be bonded together at their intersections in one embodiment. Stacking may allow the use of lower density integrated circuits with lower defect densities, and lower costs in some embodiments.

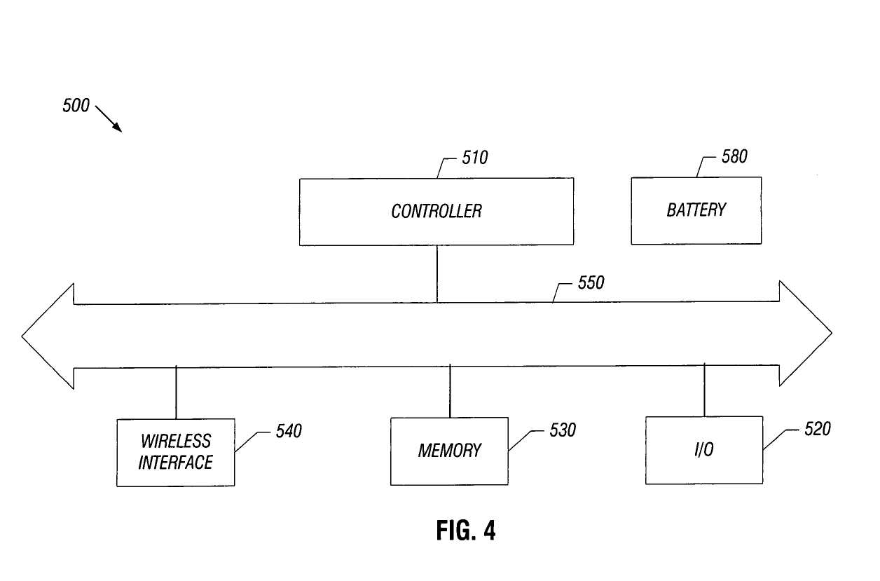

Turning to FIG. 4, a portion of a system 500 in accordance with an embodiment of the present invention is described. System 500 may be used in wireless devices such as, for example, a cellular telephone, personal digital assistant (PDA), a laptop or portable computer with wireless capability, a web tablet, a wireless telephone, a pager, an instant messaging device, a digital music player, a digital camera, or other devices that may be adapted to transmit and/or receive information wirelessly. System 500 may be used in any of the following systems: a wireless local area network (WLAN) system, a wireless personal area network (WPAN) system, or a cellular network, although the scope of the present invention is not limited in this respect.

System 500 may include a controller 510, an input/output (I/O) device 520 (e.g. a keypad, display), a memory 530, and a wireless interface 540, coupled to each other via a bus 550. A battery 580 may supply power to the system 500 in one embodiment. It should be noted that the scope of the present invention is not limited to embodiments having any or all of these components.

Controller 510 may comprise, for example, one or more microprocessors, digital signal processors, micro-controllers, or the like. Memory 530 may be used to store messages transmitted to or by system 500. Memory 530 may also optionally be used to store instructions that are executed by controller 510 during the operation of system 500, and may be used to store user data. The instructions may be stored as digital information and the user data, as disclosed herein, may be stored in one section of the memory as digital data and in another section as analog memory. As another example, a given section at one time may be labeled as such and store digital information, and then later may be relabeled and reconfigured to store analog information. Memory 530 may be provided by one or more different types of memory. For example, memory 530 may comprise a volatile memory (any type of random access memory), a non-volatile memory such as a flash memory, and/or phase change memory that includes a memory element such as, for example, memory illustrated in FIG. 1.

The I/O device 520 may be used to generate a message. The system 500 may use the wireless interface 540 to transmit and receive messages to and from a wireless communication network with a radio frequency (RF) signal. Examples of the wireless interface 540 may include an antenna, or a wireless transceiver, such as a dipole antenna, although the scope of the present invention is not limited in this respect. Also, the I/O device 520 may deliver a voltage reflecting what is stored as either a digital output (if digital information was stored), or it may be analog information (if analog information was stored).

While an example in a wireless application is provided above, embodiments of the present invention may also be used in non-wireless applications as well.

In some embodiments of the present invention, the memory 530 may be utilized as non-volatile memory that replaces a flash memory and to perform the functions normally performed by such a flash memory. More particularly, a relatively low cost flash memory, such as a NAND flash memory, may be replaced with the phase change memory 530. The phase change memory 530 may have sufficiently high performance that a static random access memory or dynamic random access memory need not be coupled, as a buffer, to the phase change memory 530 to provide sufficient performance. Thus, the memory 530 may be directly accessed by the controller 510 without using such buffering.

Moreover, the phase change memory 530 may be of sufficiently low cost. One reason for its low cost is that multilevel cells are not required to achieve low costs. Thus, the phase change memory 530 may have relatively high performance compared to NAND flash chips, at relatively low cost. The low cost may be due to the smaller phase change memory cell size. As a result, a lower cost structure with relatively high performance may be provided in place of a flash memory.

In some embodiments, the phase change memory 530 may not only provide sufficient performance (i.e., at least comparable to that of a NAND flash memory) at a relatively low cost (e.g., at least comparable to a NAND flash memory), but it may do so at sufficiently high performance that buffer chips, such as static random access memories or dynamic random access memories, need not be stacked upon and packaged with the phase change memories 530. Thus, relative to stacks of random access or static random access memories on flash chips, the memory 530 may have size and space advantages.

In one embodiment of the present invention, the phase change memory 530 may allow byte writes. The memory 530 may write a one in 20 nanoseconds or less and a zero in 200 nanoseconds or less while reading a one or a zero in 50 nanoseconds or less. Thus, without a SRAM or DRAM buffer, the memory 530 may write a one or zero in times comparable to those of NAND flash memories that are buffered by SRAM or DRAM.

Thus, the phase change memory 530 may replace NAND flash and combinations of NAND flash with buffers (such as static random access memory or dynamic random access memory). Since flash memories use block erase, they are relatively slow compared to phase change memories. In flash memories, to change a very small portion of a block, the whole block must be copied to another location, erased, and then reloaded with the new data. With phase change memory, byte writes may be used. With a byte write, any bit may be changed without affecting any other bits. In some cases, the phase change memory 530 may also replace or supplement hard disk drives, as well as other memory types.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a processor-based system including a processor and a non-volatile memory accessed directly by said processor without using a buffer memory between said non-volatile memory and the processor.

2. The method of claim 1 wherein forming a processor-based system includes forming a cell phone.

3. The method of claim 1 including forming a processor-based system with a non-volatile memory in the form of a phase change memory.

4. The method of claim 3 including forming said system with a phase change memory that has a write access time comparable to a flash memory.

5. The method of claim 1 including forming said system with a non-volatile memory accessed without using a dynamic random access memory or a static random access memory.

6. The method of claim 1 including forming said processor-based system with a non-volatile memory which is byte writable.

7. The method of claim 1 including forming said processor-based system with a non-volatile memory that is not block erased.

8. The method of claim 1 including forming said processor-based system with a non-volatile memory that does not use multilevel cells.

9. The method of claim 1 including forming said processor-based system with a non-volatile memory having the ability to write a one in 20 nanoseconds or less and a zero in 200 nanoseconds or less.

10. The method of claim 9 including forming said system with a memory that can read a one or zero in 50 nanoseconds or less.

11. An apparatus comprising:
a non-volatile memory array that is directly accessible by a processor without using a buffer on said memory array.

12. The apparatus of claim 11 wherein said array includes chalcogenic memory elements.

13. The apparatus of claim 11 that does not include a buffer in the form of a dynamic random access or static random access memory.

14. The apparatus of claim 11 wherein said apparatus is byte writable.

15. The apparatus of claim 11 wherein said apparatus is not block erasable.

16. The apparatus of claim 11 wherein said apparatus does not include multilevel cells.

17. The apparatus of claim 11 wherein said apparatus can write a one in 20 nanoseconds or less and a zero in 200 nanoseconds or less.

18. The apparatus of claim 17 wherein said apparatus can read a one or zero in 50 nanoseconds or less.

19. The apparatus of claim 1 wherein said apparatus includes two separate integrated circuits stacked one on top of the other prior to packaging.

20. The apparatus of claim 19 wherein said integrated circuits have a length and a width, and are generally rectangularly shaped such that said integrated circuits are stacked transversely to one another.

21. The apparatus of claim 11 wherein said array includes cells that include a memory element and a selection device.

22. The apparatus of claim 21 wherein said selection device includes a chalcogenide.

23. A system comprising:
a processor;
a battery coupled to said processor; and
a non-volatile memory coupled to said processor that is directly accessible by said processor without using a buffer on said memory.

24. The system of claim 23 wherein said memory includes chalcogenic memory elements.

25. The system of claim 23 wherein said memory is byte writable.

26. The system of claim 23 wherein said memory can write a one in 20 nanoseconds or less and a zero in 200 nanoseconds or less.

27. The system of claim 26 wherein said memory can read a one or a zero in 50 nanoseconds or less.

28. The system of claim 23 wherein said memory includes two separately packaged integrated circuits stacked one on top of the other.

29. The system of claim 27 wherein said integrated circuits have a length and a width, and are generally rectangularly shaped such that said integrated circuits are stacked transversely to one another.

30. The system of claim 23 wherein said memory includes cells with a memory element and a selection device.

31. The system of claim 29 wherein said selection device includes a chalcogenide.
